(19) United States
(12) Patent Application Publication
(10) Pub. No.: US 2017/0069564 A1
(43) Pub. Date: Mar. 9, 2017

(54) SEMICONDUCTOR PACKAGE AND METHOD OF MANUFACTURING THE SAME

(71) Applicant: NEPES CO., LTD., Chungcheongbuk-do (KR)

(72) Inventors: Yong-Tae KWON, Chungcheongbuk-do (KR); Jun-Kyu LEE, Chungcheongbuk-do (KR)

(21) Appl. No.: 15/255,500

(22) Filed: Sep. 2, 2016

(30) Foreign Application Priority Data
Sep. 4, 2015 (KR) 10-2015-0125442

(51) Int. Cl. H01L 23/495; H01L 21/56; H01L 23/31; H01L 23/29; H01L 25/065; H01L 25/00

(52) U.S. Cl. CPC H01L 23/49575; H01L 25/0657; H01L 25/50; H01L 23/3128; H01L 23/293; H01L 21/563; H01L 23/3135; H01L 2225/06513; H01L 2225/0651; H01L 2225/06548

(57) ABSTRACT

Disclosed herein is a wire-bonding type semiconductor package in which a fan out metal pattern is formed and a method of manufacturing the same. The semiconductor package includes a frame configured to transfer an electrical signal between upper and lower parts and having a through part formed therein, a first semiconductor chip accommodated in the through part, a first encapsulant with which the frame and the first semiconductor chip are integrally molded, a second semiconductor chip stacked on the first semiconductor chip, a wire configured to electrically connect the second semiconductor chip to a signal unit of the frame, a second encapsulant with which the second semiconductor chip and the wire are integrally molded, and a wiring unit provided below the frame and the first semiconductor chip and electrically connected to the frame and the first semiconductor chip.

### CROSS-REFERENCE TO RELATED APPLICATION

This application claims the benefit of Korean Patent Application No. 2015-0125442, filed on Sep. 4, 2015 in the Korean Intellectual Property Office, the disclosure of which is incorporated herein by reference.

### BACKGROUND

1. Field

Embodiments of the present disclosure relate to a semiconductor package and a method of manufacturing the same, and more particularly, to a wire-bonding type semiconductor package in which a fan out metal pattern is formed and a method of manufacturing the same.

2. Description of the Related Art

Recently, in semiconductor device, due to subdivision of process technologies and diversification of functions, a size of a chip is reduced and the number of input and output terminals is increased, and thus an electrode pad pitch is being gradually miniaturized. With accelerated convergence of various functions, a system-level packaging technique in which many devices are integrated into a single package has emerged. Further, the system-level packaging technique is being changed to a form of a three-dimensional stacking technique which can maintain a short signal distance in order to minimize noise between operations and improve a speed of a signal.

Meanwhile, in addition to such requirements of technical improvement, in order to control the increase of product prices, increase productivity, and reduce manufacturing costs, a semiconductor package formed by stacking a plurality of semiconductor chips is being introduced. For example, a multi-chip package (MCP) in which a plurality of semiconductor chips are stacked in a single semiconductor package, and a system in package (SiP) in which different types of stacked chips operate as a single system are being implemented.

In a conventional stack package, a tape is attached to a panel, a semiconductor chip is stacked on the tape, and a semiconductor chip pad is electrically connected to a frame pad by bonding the semiconductor chip pad to the frame pad with wires. Heat having a predetermined temperature or more is necessary for the wire bonding. In this case, since the tape is deformed due to applied heat, unintentional movement (drift) of the semiconductor chip and the frame which are attached to each other occurs. In a process of forming a circuit at an opposite side (a build-up process), since a degree of contact accuracy is reduced in a process of connecting a pad of a semiconductor chip and a pad of a frame to external terminals, a problem in that it is difficult to be applied to a product having a fine pitch occurs.

A semiconductor package having bonding wires is disclosed in Korean Laid-open Patent Publication No. 10-2009-0043955.

### DOCUMENT OF RELATED ART

### Patent Document

Korean Laid-open Patent Publication No. 10-2009-0043955 (Published on May 7, 2009)

### SUMMARY

Therefore, it is an aspect of the present disclosure to provide a semiconductor package for preventing a semiconductor chip or a frame from being moved when wires are bonded, and a method of manufacturing the same.

Additional aspects of the disclosure will be set forth in part in the description which follows and, in part, will be obvious from the description, or may be learned by practice of the disclosure.

In accordance with one aspect of the present invention, a semiconductor package includes a frame configured to transfer an electrical signal between upper and lower parts and having a through part formed therein, a first semiconductor chip accommodated in the through part, a first encapsulant with which the frame and the first semiconductor chip are integrally molded, a second semiconductor chip stacked on the first semiconductor chip, a wire configured to electrically connect the second semiconductor chip to a signal unit of the frame, a second encapsulant with which the second semiconductor chip and the wire are integrally molded, and a wiring unit provided below the frame and the first semiconductor chip and electrically connected to the frame and the first semiconductor chip.

The wiring unit may include a wiring layer, which is electrically connected to signal pads of the first semiconductor chip and extends to an outside of the first semiconductor chip, and an insulating layer which insulates the wiring layer.

The semiconductor package may further include external connection terminals provided on a surface opposite a surface at which the first semiconductor chip is located on the wiring unit, and electrically connected to the wiring layer.

The semiconductor package may be provided in a fan out type in which a virtual area formed by connecting the external connection terminals located at an edge of the first semiconductor chip is greater than a virtual area formed by connecting the signal pads located at the edge of the first semiconductor chip.

The frame may be provided as a lead frame including a conductive material.

The frame may be provided as a via frame in which a via hole is formed and the via hole is filled with a conductive material.

The semiconductor package may further include a third semiconductor chip stacked on one surface of the second semiconductor chip having the other surface facing the first semiconductor chip.

The second semiconductor chip and the third semiconductor chip may be disposed so that active surfaces thereof face each other, and the second semiconductor chip and the third semiconductor chip are electrically connected through a solder ball or a bump.

The semiconductor package may further include a die adhesive layer interposed between the first semiconductor chip and the second semiconductor chip.

The die adhesive layer may include an epoxy resin.

The first semiconductor chip and the second semiconductor chip may be disposed so that inactive surfaces thereof face each other, the inactive surface of the first semiconductor chip is attached to one surface of the die adhesive layer, and the inactive surface of the second semiconductor chip is attached to the other surface of the die adhesive layer.

In accordance with another aspect of the present invention, a method of manufacturing a semiconductor package includes disposing a first semiconductor chip on a carrier to be accommodated in a through part of a frame, molding the frame and the first semiconductor chip using a first encapsulant and integrating the frame and the first semiconductor chip into a single structure, mounting a second semiconductor chip on the first semiconductor chip, and electrically connecting the second semiconductor chip to the frame through wire bonding.

The first semiconductor chip may be disposed on the carrier so that an active surface thereof faces downward, and the second semiconductor chip may be disposed on the first semiconductor chip so that an inactive surface thereof faces downward.

The first semiconductor chip and the second semiconductor chip may be fixedly adhered to each other using a die adhesive layer.

The first semiconductor chip molded using the first encapsulant, and the second semiconductor chip and a wire, which are disposed on the frame, may be molded using a second encapsulant.

After the molding using the first encapsulant and before the mounting of the second semiconductor chip, a wiring unit may be formed so that an active surface of the first semiconductor chip is electrically connected to one surface of the frame.

### BRIEF DESCRIPTION OF THE DRAWINGS

These and/or other aspects of the disclosure will become apparent and more readily appreciated from the following description of the embodiments, taken in conjunction with the accompanying drawings of which:

FIG. 1 is a cross-sectional view of a semiconductor package according to one embodiment of the present disclosure.

FIGS. 2 to 12 are cross-sectional views illustrating the process of manufacturing the semiconductor package according to one embodiment of the present disclosure.

FIG. 13 is a cross-sectional view of a semiconductor package according to another embodiment of the present disclosure.

FIG. 14 is a cross-sectional view of a semiconductor package according to still another embodiment of the present disclosure.

### DETAILED DESCRIPTION

Hereinafter, embodiments of the present disclosure will be described in detail with reference to the accompanying drawings. The following embodiments are intended to fully convey the scope of the present disclosure to those skilled in the art and are not limited only to the embodiments presented by the present disclosure. The present disclosure may be embodied in many different forms. Parts irrelevant to description are omitted in the drawings in order to clearly explain the present disclosure, and widths, lengths, thicknesses, and the like of components may be exaggerated for convenience of description. Throughout this specification, like reference numerals in the drawings denote like elements. Further, the term “and/or” used herein includes any and all combinations of one or more referents.

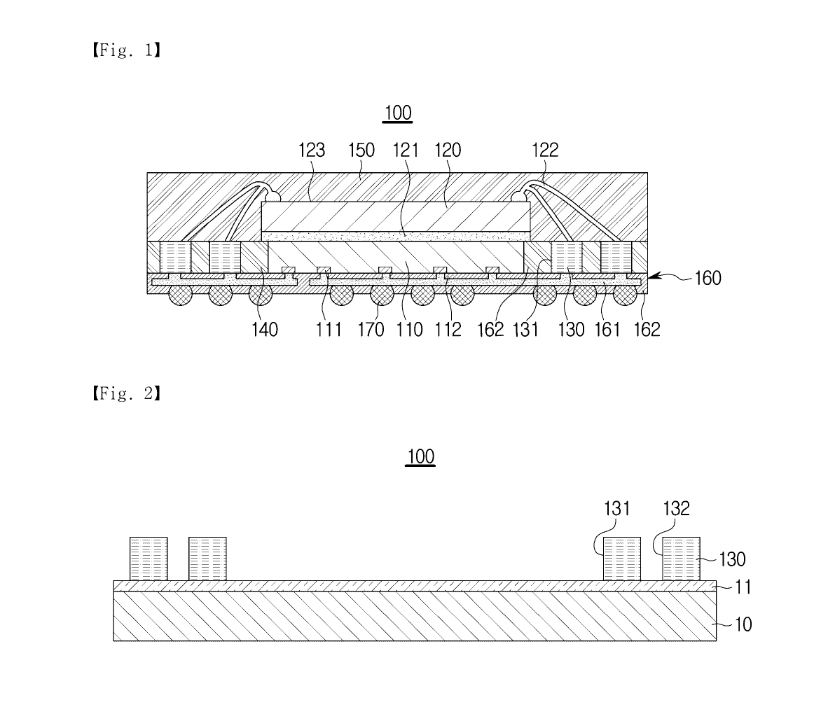

FIG. 1 is a cross-sectional view of a semiconductor package 100 according to one embodiment of the present disclosure.

The semiconductor package 100 according to one embodiment of the present disclosure includes a frame 130, a first semiconductor chip 110 accommodated in an opening of the frame 130, a first encapsulant 140 with which the frame 130 and the first semiconductor chip 110 are integrally molded, a second semiconductor chip 120 stacked on the first semiconductor chip 110, wires 122 which electrically connect the second semiconductor chip 120 to a signal unit of the frame 130, a second encapsulant 150 with which the second semiconductor chip 120 and the wires 122 are integrally molded, a wiring unit 160 electrically connected to the first semiconductor chip 110, and external connection terminals 170 which are connected to the wiring unit 160 and connect the semiconductor package 100 to external circuits (not illustrated).

The first semiconductor chip 110 and the second semiconductor chip 120 may be memory chips or logic chips. For example, the memory chips may include a dynamic random-access memory (DRAM), a static RAM (SRAM), a flash memory, a phase-change RAM (PRAM), a resistive RAM (ReRAM), a ferroelectric RAM (FeRAM), a magnetoresistive RAM (MRAM), and the like. For example, the logic chip may be a controller for controlling memory chips.

The first semiconductor chip 110 and the second semiconductor chip 120 may be the same type or different types. For example, the first semiconductor chip 110 and the second semiconductor chip 120 may be provided to be different types, and may be implemented as a system in package (SiP) in which the first semiconductor chip 110 and the second semiconductor chip 120 are electrically connected to each other and operate as a single system.

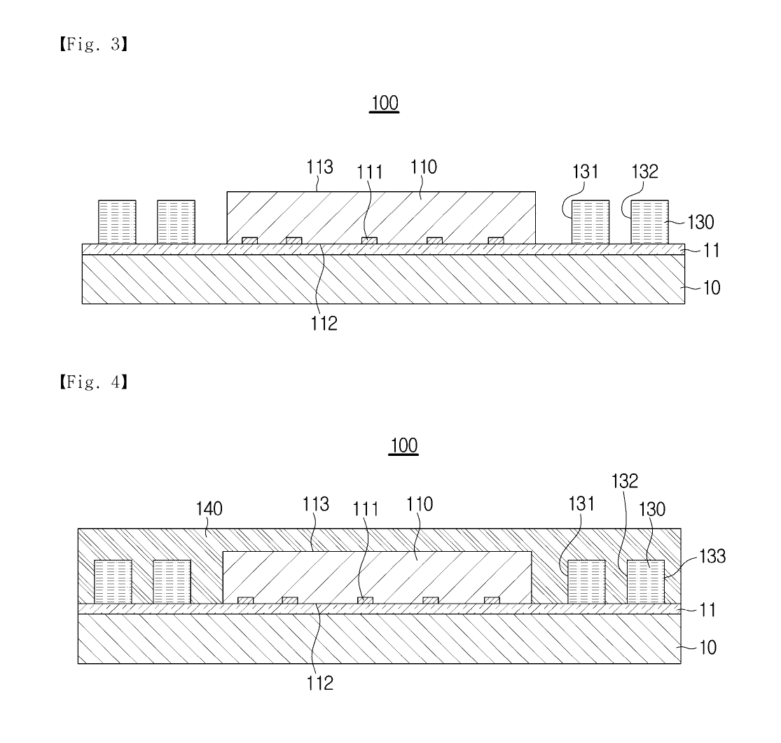

The first semiconductor chip 110 may include an active surface 112 including an active area in which a circuit is formed. An opposite surface of the active surface 112 may be an inactive surface 113 (see FIG. 3). Signal pads 111 for exchanging signals with the outside may be formed on the active surface 112. The signal pads 111 are integrated with the semiconductor chip 110.

The signal pads 111 are electrically connected to the wiring unit 160. The signal pads 111 and the wiring unit 160 may be connected using a bump or a conductive adhesive material. For example, the signal pads 111 and the wiring unit 160 may be connected through a solder joint bonding using a molten material of a metal (e.g., lead (Pb) or tin (Sn)).

The frame 130 may be electrically connected to the first semiconductor chip 110 and the second semiconductor chip 120. The frame 130 may transfer an electrical signal of the second semiconductor chip 120 disposed at an upper side to the wiring unit 160 disposed at a lower side.

The frame 130 may serve as a supporting member which supports the semiconductor package 100. The frame 130 may serve as a framework which protects the semiconductor chips from external moisture, shocks, or the like and supports the semiconductor chips.

The frame 130 may be a lead frame. The lead frame may be provided as an alloy containing iron (Fe) or copper (Cu). Particularly, when a semiconductor chip having a large amount of heat is used, a lead frame including copper having good thermal conductivity as a main component may be used. In addition, an alloy lead frame which is a Fe—Ni alloy based lead frame having a coefficient of thermal expansion similar to that of silicon may be used according to a use characteristic of the semiconductor package 100.

A plurality of through parts 131 and 132 (see FIG. 2) may be formed in the frame 130. The through part 131 formed close to the center of FIG. 1 may accommodate the first semiconductor chip 110, the through parts 132 may be formed at peripheral portions to separate adjacent frames 130, and thus respective signals may be separately transferred when the frame 130 is connected to the second semiconductor chip 120 through the plurality of wires 122. The through parts 131 and 132 of the frame 130 may be formed through a stamping process or an etching process.

Meanwhile, although not illustrated in the drawing, the frame 130 may include a plurality of signal leads (not illustrated). The signal leads may be attached to one surface of the frame 130.

The first semiconductor chip 110, the frame 130, and the wiring unit 160 may be integrally molded by the first encapsulant 140. The first encapsulant 140 may include an insulating material such as an epoxy mold compound (EMC) or an encapsulant.

The first encapsulant 140 may be injected in a fluid state and then cured in a high temperature environment. For example, the first encapsulant 140 may be simultaneously heated and pressed, and in this case, a gas and the like inside the first encapsulant 140 may be removed by additionally performing a vacuum process. The frame 130, the first semiconductor chip 110, and the wiring unit 160 are integrated into a single structure while the first encapsulant 140 is cured.

The first encapsulant 140 may be filled and molded between the through parts 131 and 132 of the frame 130. For example, the first encapsulant 140 may be filled between side surfaces of the first semiconductor chip 110 and the through part 131 located close to the center of the frame 130, and the through parts 132 (see FIG. 3) located between the frame 130 and an adjacent frame 130.

Further, the first encapsulant 140 may insulate the frame 130 from the outside by being molded to surround outer sides 133 (see FIG. 4) of the frame 130. Referring to FIG. 1, the frame 130 may be located toward an inside of the wiring unit 160 rather than an edge of the wiring unit 160. Therefore, the first encapsulant 140 may surround the outer sides 133 of the frame 130 while being molded on the wiring unit 160.

The wiring unit 160 may electrically connect the first semiconductor chip 110 to the external connection terminals 170. The wiring unit 160 may be formed in, for example, a relocation process of metal wirings. The wiring unit 160 may include a conductive material such as a metal or the like, and may include, for example, copper, a copper alloy, aluminum, or an aluminum alloy. Further, the wiring unit 160 may be formed with a pre-manufactured substrate, and may be adhered to the first semiconductor chip 110 by crimping, adhesion, reflow, and the like.

The wiring unit 160 may include an insulating layer 162 and a wiring layer 161. The insulating layer 162 may include an organic or inorganic insulating material. For example, the insulating layer 162 may include an epoxy resin.

The insulating layer 162 may be formed to have a two-layered structure, and the wiring layer 161 may be interposed between two layers of the insulating layer 162. That is, the insulating layer 162 may include a first insulating layer which insulates the first semiconductor chip 110 from the wiring layer 161, and a second insulating layer which insulates the wiring layer 161 from the outside.

The wiring layer 161 may include a conductive material such as a metal. For example, the wiring layer 161 may include copper, aluminum, or an alloy thereof.

The wiring unit 160 may re-wire the first semiconductor chip 110 and thus a circuit may be formed. Such a process is referred to as a build-up process. That is, the first semiconductor chip 110 is re-wired through the wiring unit 160, and thus the semiconductor package 100 may have a fan out structure. Therefore, input and output terminals of the first semiconductor chip 110 may be miniaturized, and at the same time, the number of the input and output terminals may be increased.

In the semiconductor package 100 having a fan out structure, a connection area of the external connection terminal 170 is provided to be wider than an active area of the first semiconductor chip 110. Here, the connection area of the external connection terminal 170 refers to an area formed when an outermost external connection terminal 170 is connected, and the active area of the first semiconductor chip 110 refers to an area formed when an outermost signal pad 111 is connected.

The external connection terminals 170 are connected to a lower portion of the wiring unit 160 to electrically connect the semiconductor package 100 to an external substrate (not illustrated), another semiconductor package (not illustrated), or the like. In FIG. 1, although a solder ball is illustrated as an example of the external connection terminal 170, the external connection terminal 170 includes a solder bump and the like. Further, surface processing such as organic coating, metal plating, and the like is performed on surfaces of the external connection terminals 170, and thus the surfaces of the external connection terminals 170 may be prevented from being oxidized. For example, the organic coating may be organic solder preservation (OSP) coating, and the metal plating may be performed using a gold (Au), nickel (Ni), lead (Pb), or silver (Ag) plating.

The second semiconductor chip 120 may be stacked on the first semiconductor chip 110. Since the description of the first semiconductor chip 110 may be applied to the second semiconductor chip 120 in the same manner, a detailed description thereof will be omitted.

The second semiconductor chip 120 may be attached to the first semiconductor chip using a die adhesive layer 121 as a medium. For example, the die adhesive layer 121 may include an epoxy resin.

The die adhesive layer 121 may be provided in an adhesive film form, and when the die adhesive layer 121 is provided in a double-sided adhesive film from, the first semiconductor chip 110 may be attached to one surface of the double-sided adhesive film and the second semiconductor chip 120 may be attached to the other surface of the double-sided adhesive film. Alternatively, the first semiconductor chip 110 may be coated with the die adhesive layer 121 in a resin form. In this case, the die adhesive layer 121 may attach the second semiconductor chip 120 to the first semiconductor chip 110 in a process in which the second semiconductor chip 120 is stacked and then cured.

Since the second semiconductor chip 120 is mounted on the first semiconductor chip 110 which forms a single structure with the frame 130 by the first encapsulant 140, a width of the second semiconductor chip 120 is not limited to a width of the first semiconductor chip 110. That is, the width of the second semiconductor chip 120 may be greater than the width of the first semiconductor chip 110.

The wires 122 electrically connect the second semiconductor chip 120 to the frame 130. That is, the second semiconductor chip 120 is electrically connected to the frame 130 by bonding with the wires 122 (wire bonding). The wires 122 including gold (Au) having good conductivity may be provided, or the wires 122 including copper (Cu) may be provided in consideration of economic efficiency.

Meanwhile, although not illustrated in the drawing, semiconductor chips such as a third semiconductor chip or the like may be additionally stacked on the second semiconductor chip 120. In this case, the third semiconductor chip may be bonded to the frame 130 with the wires 122. Alternatively, the third semiconductor chip may be directly connected to the second semiconductor chip 120 through bumps or solder balls.

The second encapsulant 150 may be molded for the first semiconductor chip 110 integrated using the first encapsulant 140, and the second semiconductor chip 120 and the wires 122, which are disposed on the frame 130. The second encapsulant 150 may be molded to cover up to an upper surface 123 of the second semiconductor chip 120. Since the description of the first encapsulant 140 may be applied to the second encapsulant 150 in the same manner, a detailed description thereof will be omitted.

Next, a process of manufacturing a semiconductor package 100 will be described with reference to the drawings. FIGS. 2 to 12 are cross-sectional views illustrating the process of manufacturing the semiconductor package 100 according to one embodiment of the present disclosure.

FIG. 2 illustrates a state in which a frame 130 is disposed on a carrier 10. The frame 130 may be fixed to the carrier 10 using an adhesive layer 11. A through part 131 may be formed close to the center of the frame 130, and a plurality of through parts 132 may be formed at a periphery of the through part 131 formed close to the center thereof.

The carrier 10, which supports the frame 130 and a first semiconductor chip 110, may be formed of a material having high rigidity and low thermal strain. The carrier 10 may be formed of a rigid type material, for example, a material such as a molding, a polyimide tape, and the like.

A double-sided adhesive film may be used as the adhesive layer 11, one surface of the adhesive layer 11 may be fixedly attached to the carrier 10, and the frame 130 may be attached to the other surface of the adhesive layer 11.

FIG. 3 illustrates a state in which a first semiconductor chip 110 is disposed on the carrier 10. The first semiconductor chip 110 may be disposed to be accommodated between the through parts 131 disposed close to the center of the frame 130. Both side surfaces of the semiconductor chip 110 may be spaced apart from the frame 130.

The first semiconductor chip 110 may be disposed on the carrier 10 so that an active surface 112 thereof faces downward. In FIG. 3, although the active surface 112 of the first semiconductor chip 110 is illustrated as being directly attached to the adhesive layer 11, a signal transmission unit (not illustrated) which is electrically connected to the signal pads 111 may be adhered to the adhesive layer 11, and thus the first semiconductor chip 110 may be spaced apart from the adhesive layer 11.

Meanwhile, although the single semiconductor package 100 is illustrated as being manufactured on the carrier 10 in the drawing, a plurality of frames 130 and first semiconductor chips 110 are attached on the carrier 10 at predetermined intervals, and thus a plurality of semiconductor packages 100 may be simultaneously manufactured in a single process.

FIG. 4 illustrates a state in which the first semiconductor chip 110 and the frame 130 are sealed with a first encapsulant 140. The first encapsulant 140 may be injected between the carrier 10 and an upper mold (not illustrated) in a fluid state to be provided on the carrier 10, and may be pressed and cured by the upper mold in a high temperature environment.

The first encapsulant 140 is poured in a mold, is filled between the frame 130 and an adjacent frame 130 and between the frame 130 and the first semiconductor chip 110, surrounds both side portions of the frame 130, and is molded to cover upper portions of the frame 130 and the first semiconductor chip 110. The first encapsulant 140 is cured with the passage of time, and the frame 130 and the first semiconductor chip 110 are integrated during this process.

Although the injecting of the first encapsulant 140 in a fluid state is described as a method of sealing with the first encapsulant 140, a method such as coating, printing, or the like may be used. Further, various techniques conventionally used in the art may be used as a method of molding the first encapsulant 140.

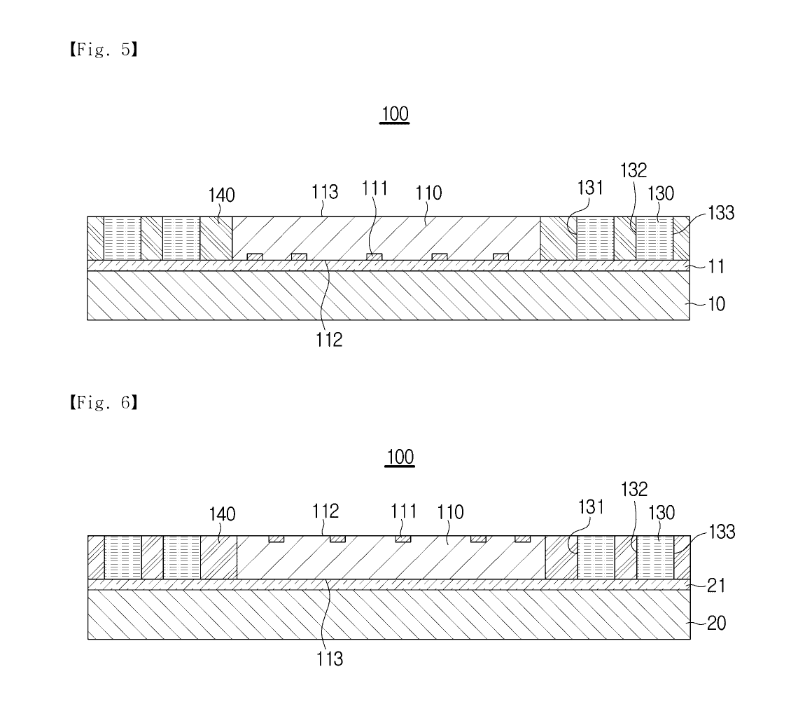

FIG. 5 illustrates a state in which an upper surface of the first encapsulant 140 is planarized. After the first encapsulant 140 is cured and the upper mold is removed, a planarization process for grinding the upper surface of the first encapsulant 140 is performed.

FIG. 6 illustrates a state in which the existing carrier 10 and adhesive layer 11 are removed and a carrier 20 and an adhesive layer 21 are provided on an opposite surface. In order to form a wiring unit 160, the carrier 20 is newly provided on the opposite surface.

In a state in which the first encapsulant 140 is firmly cured, the carrier 10 and the adhesive layer 11 may be removed. Since the carrier 10 is removed, the active surface 112 (specifically, the signal pads 111) of the first semiconductor chip 110 is exposed to the outside.

Next, the first semiconductor chip 110 is disposed on the carrier 20 so that the active surface 112 thereof faces upward. In this case, the first semiconductor chip 110 is also fixed to the carrier 20 using the adhesive layer 21 as a medium.

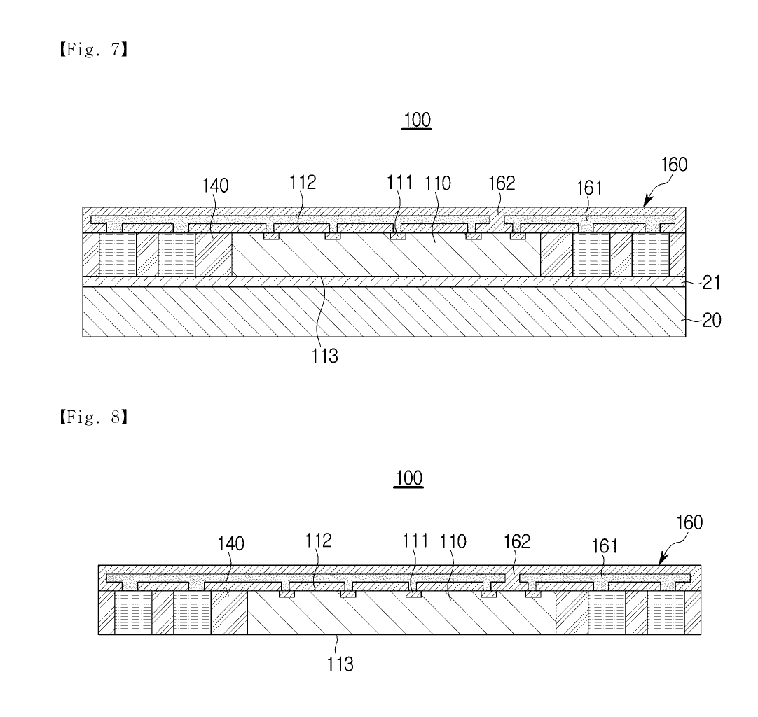

FIG. 7 illustrates a state in which the wiring unit 160 is formed.

To describe a process of forming the wiring unit 160 in detail, first, a first insulating layer is stacked on the active surface 112 of the first semiconductor chip 110, the first encapsulant 140, and the frame 130, and the signal pads 111 of the first semiconductor chip 110 and a portion of the frame 130 are exposed. An etching method using laser processing, chemical processing, or the like may be used as the method of exposing a portion of the first insulating layer. Next, a wiring layer 161 is formed on the first insulating layer. The wiring layer 161 may be stacked in a state in which a pattern is formed in advance, or the pattern may be formed using a mask after the stacking. The wiring layer 161 may be electrically connected to the signal pads 111 and the frame 130 through an exposed portion of the first insulating layer, and a re-wiring layer may be formed. The wiring layer 161 may be formed using various methods such as deposition, plating, and the like. Finally, the wiring layer 161 is insulated by stacking the second insulating layer thereon.

FIG. 8 illustrates a state in which the carrier 20 and the adhesive layer 21 are removed. However, the process of FIG. 8 may be omitted as necessary.

FIG. 9 illustrates a state in which a second semiconductor chip 120 is mounted on the first semiconductor chip 110. The second semiconductor chip 120 may be mounted on the first semiconductor chip 110 using a die adhesive layer 121 as a medium. The die adhesive layer 121 may be provided in an adhesive film form, or the second semiconductor chip 120 may be coated with the die adhesive layer 121 in a resin form.

The second semiconductor chip 120 may be mounted on the first semiconductor chip 110 so that an inactive surface 124 thereof faces downward. That is, an inactive surface 113 of the first semiconductor chip 110 may face the inactive surface 124 of the second semiconductor chip 120. Therefore, the inactive surface 113 of the first semiconductor chip 110 is attached to one surface of the die adhesive layer 121, and the inactive surface 124 of the second semiconductor chip 120 is attached to the other surface of the die adhesive layer 121.

A width of the second semiconductor chip 120 may be greater than a width of the first semiconductor chip 110. In this case, the second semiconductor chip 120 may cover the first semiconductor chip 110 and the first encapsulant 140. Further, the second semiconductor chip 120 may cover the frame 130 unlike the drawing.

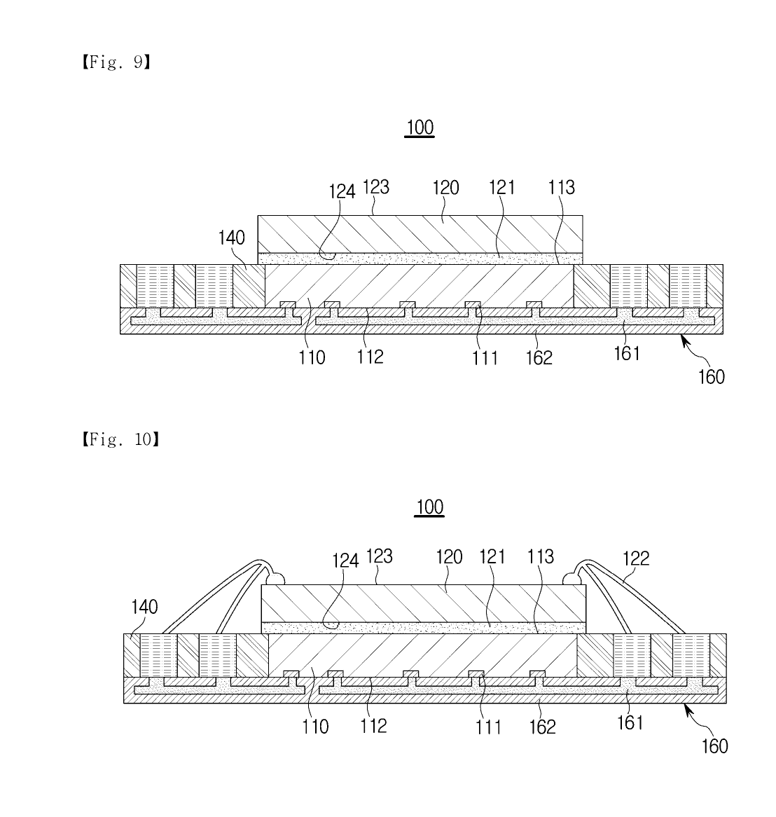

FIG. 10 illustrates a state in which bonding is performed using wires 122. The second semiconductor chip 120 may be electrically connected to the frame 130 (see FIG. 1) through the wire 122. Meanwhile, the second semiconductor chip 120 may be connected to the frame 130 through a plurality of wires 122. Referring to the drawing, two wires 122 which are bonded at a single point of the second semiconductor chip 120 may be respectively connected to different areas of the frame 130.

Meanwhile, although not illustrated in the drawing, signal leads (not illustrated) may be provided on one surface of the frame 130 to which the wires 122 are connected.

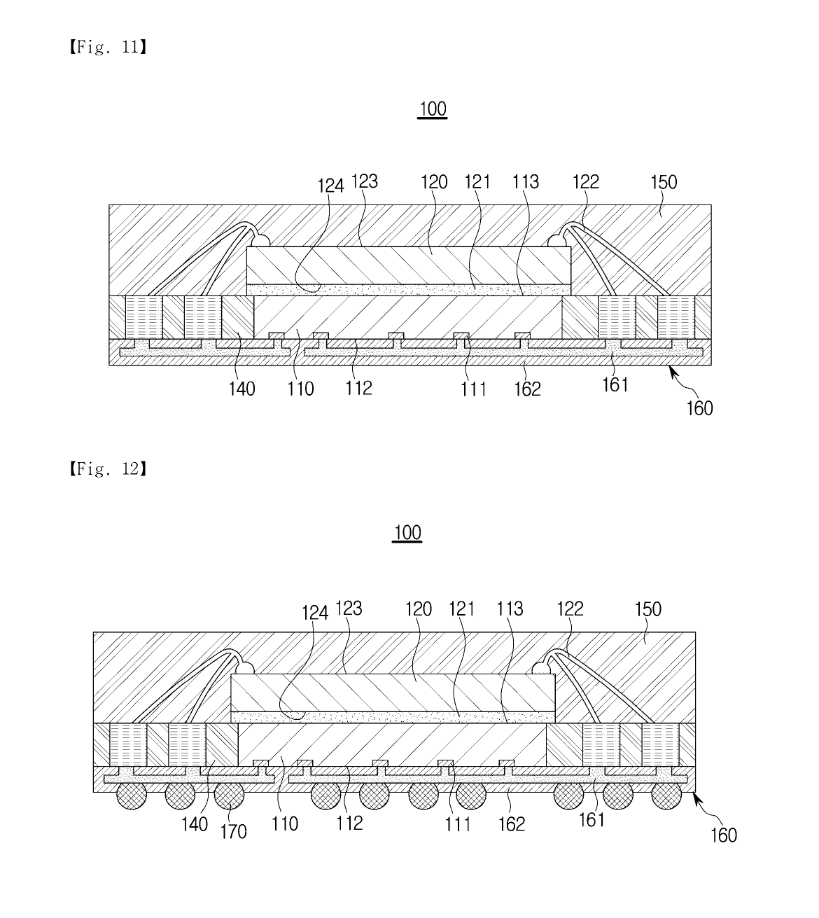

FIG. 11 illustrates a state in which a second encapsulant 150 is molded. The second encapsulant 150 may integrate the first semiconductor chip 110 which is integrated using the first encapsulant 140, and the second semiconductor chip 120 and the wires 122, which are disposed on the frame 130. The second encapsulant 150 may be molded to cover the upper surface 123 of the second semiconductor chip 120.

FIG. 12 illustrates a state in which external connection terminals 170 are connected to the wiring unit 160. The external connection terminals 170 are attached to the exposed wiring layer 161 to electrically connect the semiconductor package 100 to an external device. The external device may be a circuit board or another semiconductor package.

Meanwhile, although solder balls are illustrated as an example of the external connection terminal 170 in the drawing, the external connection terminal 170 includes solder bumps and the like.

In the semiconductor package 100 according to one embodiment of the present disclosure and the method of manufacturing the same, molding is performed in two separate processes by separating the first encapsulant 140 from the second encapsulant 150.

When the frame 130 and the first semiconductor chip 110 are disposed on the carrier 10 to which the adhesive tape 11 is attached by adhesion, the second semiconductor chip 120 is mounted on the first semiconductor chip 110 by adhesion using the die adhesive layer 121, and the frame 130, the first semiconductor chip 110, and the second semiconductor chip 120 are molded using a single encapsulant after the wires 122 are bonded, a problem may occur.

Heat at high temperature is required while the wires 122 having a metal material are bonded, and deformation of the adhesive tape 11 stacked on the carrier 10 may occur due to the heat at high temperature. Therefore, the arrangement of the first semiconductor chip 110 and the frame 130 may be unintentionally changed during the bonding. When the arrangement of the first semiconductor chip 110 or the frame 130 is changed, a degree of connection accuracy may be reduced in a subsequent build-up process in which the wiring unit 160 is formed, and thus it may be difficult to apply to a product having a fine pitch.

However, such a problem may not occur in the semiconductor package 100 according to one embodiment of the present disclosure and the method of manufacturing the same. This is because the first semiconductor chip 110 and the frame 130 are molded and integrated using the first encapsulant 140, the second semiconductor chip 120 is then mounted on the first semiconductor chip 110, and bonding is performed using the wires 122. This is because movement caused by heat applied during the bonding process of the wires 122 does not occur because the first semiconductor chip 110 and the frame 130 are already rigidly bonded to each other.

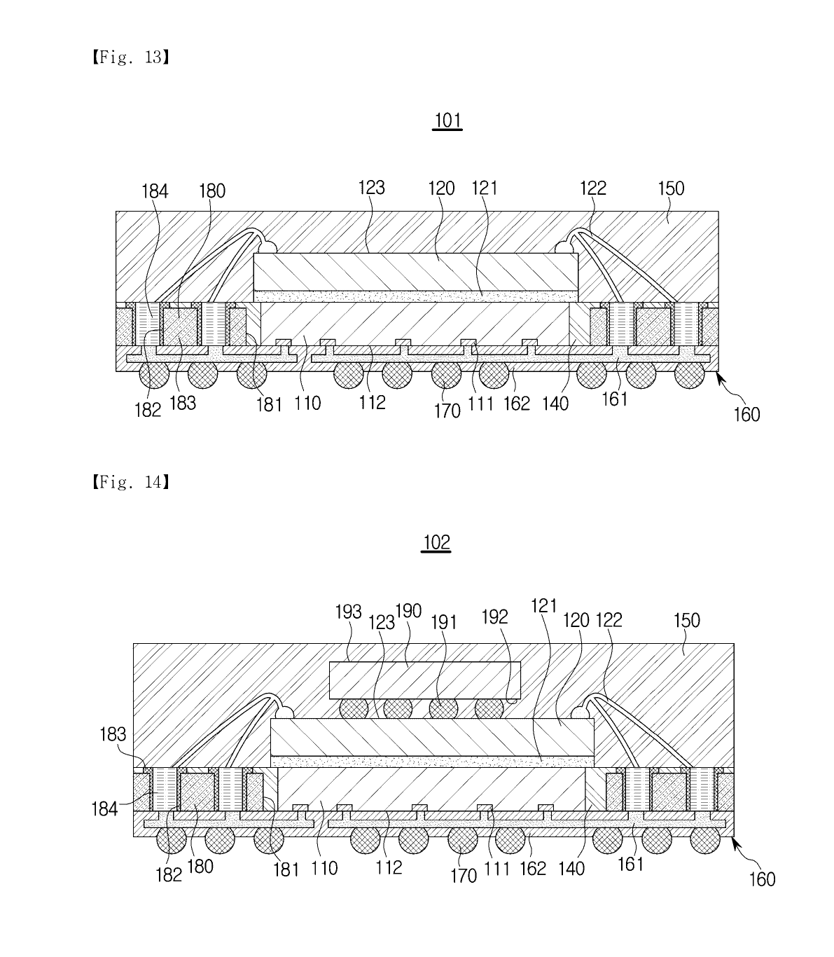

FIG. 13 is a cross-sectional view of a semiconductor package 101 according to another embodiment of the present disclosure.

A frame 180 of the semiconductor package 101 according to another embodiment of the present disclosure may be a via frame. The via frame may be provided as a substrate in which through-vias are formed. The substrate may be an insulating substrate, and the insulating substrate may include an insulating material. For example, the insulating material may include silicon, glass, ceramic, plastic, or a polymer.

A through part 181 which accommodates a first semiconductor chip 110 may be formed at the center of the frame 180, and a plurality of through parts, that is, via holes 182 may be formed at a periphery of the through part 181. Through wirings 183 provided in a vertical direction are provided in the via holes 182 formed at the periphery of the through part 181.

The through wiring 183 may transfer an electrical signal transferred from the second semiconductor chip 120 to the wiring unit 160. One side of the through wiring 183 may be electrically connected to the second semiconductor chip 120 through the wire 122, and the other side thereof may be electrically connected to the first semiconductor chip 110 and/or an external connection terminal 170 through the wiring layer 161.

The through wirings 183 are disposed in a vertical direction through the via holes 182 provided in the frame 180. The via holes 182 may be formed to pass through the frame 180, and the plurality of via holes 182 may be provided along an edge of the first semiconductor chip 110.

The through wirings 183 may be a conductive material with which the via holes 182 are filled, and may be a metal layer with which the via holes 182 are coated. The through wirings 183 may be provided to have a cylindrical shape, and a through member 184 may be accommodated in hollow portions of the through wirings 183. The through member 184 may be a non-conductive resin, and may be formed to fill the hollow portions of the through wirings 183. Meanwhile, the through member 184 may be formed of a conductive material.

Meanwhile, the through wirings 183 may be provided in a form of a solder ball or the like to pass through the via holes 182, or may be a solder resist ink with which the via holes 182 is filled.

The method of forming the through wirings 183 includes electroless plating, electroplating, sputtering, printing, or the like.

FIG. 14 is a cross-sectional view of a semiconductor package 102 according to still another embodiment of the present disclosure.

The semiconductor package 102 according to still another embodiment of the present disclosure may include a third semiconductor chip 190 stacked on a second semiconductor chip 120.

The third semiconductor chip 190 may be a different type of semiconductor chip from a first semiconductor chip 110 and/or the second semiconductor chip 120.

Referring to FIG. 14, an active surface 123 of the second semiconductor chip 120 is exposed upward, and the third semiconductor chip 190 may be mounted on the second semiconductor chip 120 so that an active surface 192 thereof faces downward. The third semiconductor chip 190 and the second semiconductor chip 120 may be electrically connected through bumps or solder balls 191.

A second encapsulant 150 may be molded to cover an inactive surface 193 of the third semiconductor chip 190. However, the second encapsulant 150 may be molded to expose the inactive surface 193 of the third semiconductor chip 190 unlike the drawing. In this case, after the third semiconductor chip 190 is mounted on the second semiconductor chip 120, the second encapsulant 150 may be molded to cover the inactive surface 193 of the third semiconductor chip 190, and then an upper surface of the second encapsulant 150 may be ground to expose the inactive surface 193 of the third semiconductor chip 190. In this case, a portion of the inactive surface 193 of the third semiconductor chip 190 may also be ground.

As is apparent from the above description, in the semiconductor package according to the embodiment of the present disclosure and the method of manufacturing the same, a lower semiconductor chip and a frame are molded and integrated first before wires are bonded, and thus the semiconductor chip and the frame can be blocked from being moved due to heat generated in a process in which the wires are bonded.

A degree of accuracy of a circuit can be improved by minimizing the movement of the semiconductor chip and the frame.

Further, since the circuit is formed (a build-up process) after the lower semiconductor chip and the frame are molded and integrated first, an upper semiconductor chip can be mounted in only an area that meets a standard after the circuit forming process, and thus loss in the process can be prevented.

Further, degrees of freedom of determination of positions of the upper semiconductor chip and the lower semiconductor chip are high regardless of sizes of the semiconductor chips. That is, even when a size of the upper semiconductor chip is greater than a size of the lower semiconductor chip, the semiconductor package can be manufactured.

Further, a fan out metal pattern is formed below the lower semiconductor chip, and thus signal pads formed in the semiconductor chip at small gaps can be more widely disposed.

While the invention has been described with reference to exemplary embodiments illustrated in accompanying drawings, these should be considered in a descriptive sense only, and it will be understood by those skilled in the art that various alterations and equivalent other embodiment may be made. Therefore, the scope of the invention is defined by the appended claims.

[Reference Numerals]

| | |
|---|---|
| 100: SEMICONDUCTOR | 110: FIRST SEMICONDUCTOR CHIP |
| PACKAGE | |
| 120: SECOND | 121: DIE ADHESIVE LAYER |
| SEMICONDUCTOR CHIP | |
| 122: WIRE | 130: FRAME |
| 140: FIRST ENCAPSULANT | 150: SECOND ENCAPSULANT |
| 160: WIRING UNIT | 170: EXTERNAL CONNECTION |
| | TERMINAL |

What is claimed is:

1. A semiconductor package comprising:
a frame configured to transfer an electrical signal between upper and lower parts and having a through part formed therein;
a first semiconductor chip accommodated in the through part;
a first encapsulant with which the frame and the first semiconductor chip are integrally molded;
a second semiconductor chip stacked on the first semiconductor chip;
a wire configured to electrically connect the second semiconductor chip to a signal unit of the frame;
a second encapsulant with which the second semiconductor chip and the wire are integrally molded; and
a wiring unit provided below the frame and the first semiconductor chip and electrically connected to the frame and the first semiconductor chip.

2. The semiconductor package according to claim 1, wherein the wiring unit includes a wiring layer, which is electrically connected to signal pads of the first semiconductor chip and extends to an outside of the first semiconductor chip, and an insulating layer which insulates the wiring layer.

3. The semiconductor package according to claim 2, further comprising external connection terminals provided on a surface opposite a surface at which the first semiconductor chip is located on the wiring unit, and electrically connected to the wiring layer.

4. The semiconductor package according to claim 3, which is provided in a fan out type in which a virtual area formed by connecting the external connection terminals located at an edge of the first semiconductor chip is greater than a virtual area formed by connecting the signal pads located at the edge of the first semiconductor chip.

5. The semiconductor package according to claim 1, wherein the frame is provided as a lead frame including a conductive material.

6. The semiconductor package according to claim 1, wherein the frame is provided as a via frame in which a via hole is formed and the via hole is filled with a conductive material.

7. The semiconductor package according to claim 1, further comprising a third semiconductor chip stacked on one surface of the second semiconductor chip having the other surface facing the first semiconductor chip.

8. The semiconductor package according to claim 7, wherein the second semiconductor chip and the third semiconductor chip are disposed so that active surfaces thereof face each other, and the second semiconductor chip and the third semiconductor chip are electrically connected through a solder ball or a bump.

9. The semiconductor package according to claim 1, further comprising a die adhesive layer interposed between the first semiconductor chip and the second semiconductor chip.

10. The semiconductor package according to claim 9, wherein the die adhesive layer includes an epoxy resin.

11. The semiconductor package according to claim 9, wherein the first semiconductor chip and the second semiconductor chip are disposed so that inactive surfaces thereof face each other, the inactive surface of the first semiconductor chip is attached to one surface of the die adhesive layer, and the inactive surface of the second semiconductor chip is attached to the other surface of the die adhesive layer.

12. A method of manufacturing a semiconductor package, the method comprising:
disposing a first semiconductor chip on a carrier to be accommodated in a through part of a frame;
molding the frame and the first semiconductor chip using a first encapsulant and integrating the frame and the first semiconductor chip into a single structure;
mounting a second semiconductor chip on the first semiconductor chip; and
electrically connecting the second semiconductor chip to the frame through wire bonding.

13. The method according to claim 12, wherein:
the first semiconductor chip is disposed on the carrier so that an active surface thereof faces downward; and
the second semiconductor chip is disposed on the first semiconductor chip so that an inactive surface thereof faces downward.

14. The method according to claim 13, wherein the first semiconductor chip and the second semiconductor chip are fixedly adhered to each other using a die adhesive layer.

15. The method according to claim 12, wherein the first semiconductor chip molded using the first encapsulant, and the second semiconductor chip and a wire, which are disposed on the frame, are molded using a second encapsulant.

16. The method according to claim 12, wherein, after the molding using the first encapsulant and before the mounting of the second semiconductor chip, a wiring unit is formed so that an active surface of the first semiconductor chip is electrically connected to one surface of the frame.
